(19) United States
(12) Patent Application Publication
(10) Pub. No.: US 2025/0308619 A1
(43) Pub. Date: Oct. 2, 2025

(54) SYSTEMS AND TECHNIQUES FOR ERROR TESTING

(71) Applicant: Micron Technology, Inc., Boise, ID (US)

(72) Inventors: Thomas Hein, München (DE); Natalija Jovanovic, München (DE); Casto Salobrena Garcia, München (DE)

(21) Appl. No.: 19/090,015

(22) Filed: Mar. 25, 2025

Related U.S. Application Data
(60) Provisional application No. 63/572,864, filed on Apr. 1, 2024.

(51) Int. Cl. G11C 29/56

(52) U.S. Cl. CPC G11C 29/56008; G11C 29/56016; G11C 2029/5602

(57) ABSTRACT

Methods, systems, and devices for systems and techniques for error testing are described. As part of a first write operation, a memory system may write data and associated error correction code (ECC) bits to a memory array. In accordance with a first portion of a test, the memory system may store a copy of the ECC bits to a register of the memory system. As part of a second write operation, the memory system may write an error vector to the memory array. In accordance with a second portion of the test, the memory system may store the previously-stored ECC bits from the register to the memory array. The memory system may subsequently access the error vector and the ECC bits from the memory array to support verification of error correction and detection performance of the memory system.

### CROSS REFERENCE

The present Application for Patent claims priority to U.S. Patent Application No. 63/572,864 by Hein et al., entitled “SYSTEMS AND TECHNIQUES FOR ERROR TESTING,” filed Apr. 1, 2024, which is assigned to the assignee hereof, and which is expressly incorporated by reference in its entirety herein.

### TECHNICAL FIELD

The following relates to one or more systems for memory, including systems and techniques for error testing.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports systems and techniques for error testing in accordance with examples as disclosed herein.

FIGS. 2 and 3 show examples of test diagrams that support systems and techniques for error testing in accordance with examples as disclosed herein.

FIG. 4 shows a block diagram of a memory system that supports systems and techniques for error testing in accordance with examples as disclosed herein.

FIG. 5 shows a flowchart illustrating a method or methods that support systems and techniques for error testing in accordance with examples as disclosed herein.

### DETAILED DESCRIPTION

Some memory systems may support the detection and correction of errors in data stored at the memory system. In some examples, a memory system may perform various tests to verify (e.g., test) the performance of the error detection and correction capabilities of the memory system. In some cases, however, such tests may be performed without data being written to a memory array of the memory system. For example, when testing error detection and correction performance, the memory system may route error vectors (e.g., data with errors injected into it) to error detection and correction circuitry without writing the error vectors to the memory array. As such, information associated with error detection and correction performance in conjunction with storing data to and retrieving data from the memory array may be unavailable. That is, test information related to error correction and detection performance associated with writing data along the full data path (e.g., to the memory array) may be unknown, and thus correction of associated errors or associated adjustment of error correction and detection circuitry of the memory system may be impossible.

In accordance with examples described herein, a memory system may include circuitry to support testing error detection and correction performance in conjunction with writing data to and reading data from a memory array of the memory system. For example, a memory system may generate error correction code (ECC) bits (e.g., check bits) corresponding to received data and may write the data and the ECC bits to the memory array. The memory system, as part of a first portion of a test, may also store a copy of the ECC bits to a register (e.g., a check bit register) of the memory system. As part of a second portion of the test, the memory system may receive and write an error vector to the memory array. For example, during the second portion of the test, a host system may modify (e.g., flip) one or more bits of the original data and transmit the modified data to the memory system. Rather than maintain new ECC bits corresponding to the modified data (e.g., error vector) for storage to the memory array, the memory system may store the previously-generated ECC bits from the register to the memory array along with storing the modified data to the memory array.

As part of a read operation, the memory system may subsequently access the modified data and the ECC bits from the memory array. Using the ECC bits, the memory system may detect one or more errors in the modified data and transmit an indication that the modified data includes the one or more errors (e.g., a severity indication) and the modified data to the host system. The modified data and the indication may enable the host system to verify whether the error detection and correction performance of the memory system along the entire data path, for example, by determining whether the quantity and location of the errors corresponds to those bits that were flipped. Verifying the error detection and correction performance of the memory system along the entire data path supports adjustments and corrections to the ECC circuitry of the memory system, which may increase reliability of the memory system, decrease access latency, and improve efficiency of the memory system.

In addition to applicability in memory systems as described herein, techniques for error testing may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving error correction and detection performance, which may increase data access reliability, decrease processing or latency times, improve response times, or otherwise improve user experience, among other benefits.

Features of the disclosure are illustrated and described in the context of systems and architectures. Features of the disclosure are further illustrated and described in the context of flowcharts.

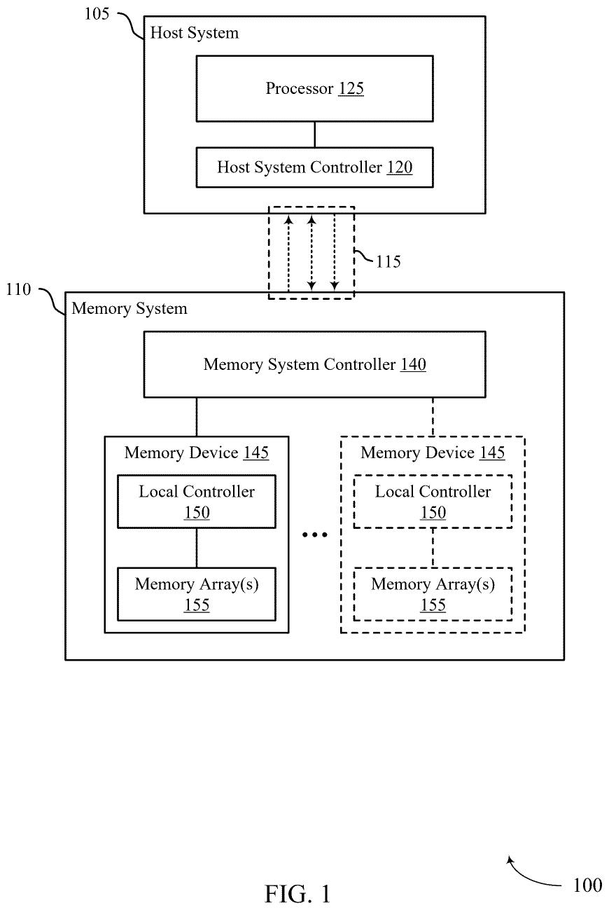

FIG. 1 illustrates an example of a system 100 that supports systems and techniques for error testing in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

Signals communicated over the channels 115 may be modulated using various modulation schemes or combinations thereof. A symbol of a binary-symbol (e.g., binary-level) modulation scheme may be operable to represent one bit of data (e.g., a symbol may represent a logic 1 or a logic 0), and may be an example of an M-ary modulation scheme where M is equal to two. Examples of binary-symbol modulation schemes include non-return-to-zero (NRZ), unipolar encoding, bipolar encoding, Manchester encoding, pulse amplitude modulation (PAM) having two symbols (e.g., PAM2), and others. A symbol of a multi-symbol modulation scheme may be operable to represent more than one bit of data (e.g., a symbol may represent a logic 00, a logic 01, a logic 10, or a logic 11), and may be an example of an M-ary modulation scheme where M is greater than or equal to three. For example, a multi-symbol signal may be modulated using a modulation scheme that includes at least three levels to encode more than one bit of information. Multi-symbol modulation schemes and symbols may be referred to as non-binary, multi-bit, or higher-order modulation schemes and symbols. Examples of multi-symbol modulation schemes include PAM3, PAM4, PAM8, and so on, quadrature amplitude modulation (QAM), quadrature phase shift keying (QPSK), and others.

The memory system 110 may support the detection and correction of errors in data stored at the memory system 110. In some examples, the host system 105 and the memory system 110 may perform various tests to verify the correct performance of the error detection and correction capabilities (e.g., correct operation of ECC circuitry) of the memory system 110. In some cases, however, such tests may be performed without data being written to a memory array 155. For example, when testing ECC circuitry, the memory system 110 may route error vectors (e.g., data with errors injected into it) received from the host system 105 directly to the ECC circuitry without writing the error vectors to the memory array 155. As such, information associated with the performance of the ECC circuitry in conjunction with storing data to and retrieving data from the memory arrays 155 may be unavailable. That is, test information related to error correction and detection performance associated with writing data along the full data path (e.g., to the memory array) may be unknown, and thus correction of associated errors or associated adjustment of error correction and detection circuitry of the memory system may be impossible.

The memory system 110 may support testing error detection and correction performance in conjunction with writing data to and reading data from a memory array 155. For example, the memory system 110 may generate ECC bits (e.g., check bits) corresponding to data received from the host system 105 and may write the data and the ECC bits to a memory array 155. As part of a first portion of a test (e.g., in accordance with a first test mode enabled by a first mode register of the memory system 110), the memory system 110 may also store a copy of the ECC bits in a register (e.g., a check bit register) of the memory system 110. As part of a second portion of the test, the memory system 110 may receive and write an error vector to the memory array 155. For example, during the second portion of the test, the host system 105 may modify (e.g., flip) one or more bits of the original data and transmit the modified data to the memory system 110. Rather than generate new ECC bits corresponding to the modified data (e.g., error vector) for storage to the memory array 155, the memory system 110 may store the previously-generated ECC bits from the register to the memory array 155 along with storing the modified data to the memory array 155.

As part of a read operation, the memory system 110 may subsequently access the modified data and the ECC bits from the memory array 155. Using ECC circuitry and the ECC bits, the memory system 110 may detect one or more errors in the modified data and transmit an indication that the modified data includes the one or more errors (e.g., a severity indication) and the modified data to the host system 105. The modified data and the indication may enable the host system 105 to verify whether the error detection and correction performance of the memory system 110 along the entire data path, for example, by determining whether the quantity and location of the errors corresponds to those bits that were flipped. Verifying the error detection and correction performance of the memory system 110 along the entire data path supports adjustments and corrections to the ECC circuitry of the memory system, which may increase reliability of the memory system 110, decrease access latency, and improve efficiency of the memory system 110.

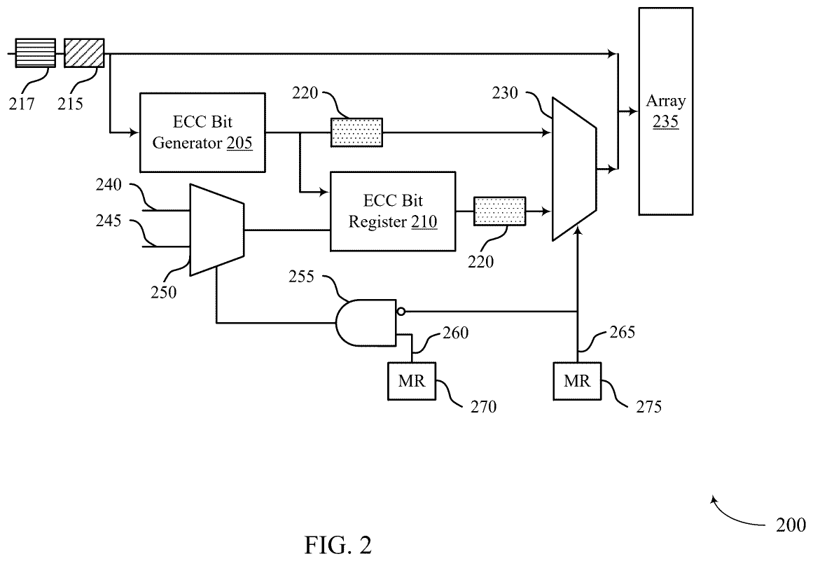

FIG. 2 illustrates an example of a test diagram 200 that supports systems and techniques for error testing in accordance with examples as disclosed herein. The test diagram 200 may be implemented by aspects of a system 100 or one or more components thereof. For example, the test diagram 200 depicts components of a memory system (e.g., a memory system 110 as described with reference to FIG. 1) that support testing error detection and correction performance of a memory system in conjunction with writing data to and reading data from a memory array (e.g., a memory array 155).

A memory system implementing the test diagram 200 may include an error control information generator, such as an ECC bit generator 205. As part of a write operation, the memory system may input data 215 (e.g., received from a host system 105) into the ECC bit generator 205, and the ECC bit generator 205 may generate one or more ECC bits 220 (e.g., check bits). For example, the memory system may route data 215 to the ECC bit generator 205, which may generate (e.g., calculate, compute) the ECC bits 220 to support error detection (e.g., and correction) associated with the data 215 (e.g., resulting from the transmission of the data 215, storage of the data 215, retrieval of the stored data 215). As part of the write operation, the memory system may store the data 215 and the ECC bits 220 to the array 235 (e.g., a memory array 155). For example, the ECC bit generator 205 may output the ECC bits 220 to the array 235. In some other examples, the ECC bit generator 205 may transmit the ECC bits 220 to an ECC bit register 210 for temporary storage.

In some examples, the memory system may perform various tests to verify the performance of its error detection and correction capabilities. In some cases, however, such tests may be performed without writing data to the array 235, which may limit the information on the memory system's error detection and correction performance that is obtained from the tests.

In accordance with examples described herein, the memory system may support testing error detection and correction performance in conjunction with writing data to and reading data from the array 235. For example, the memory system may generate ECC bits 220 (e.g., check bits) corresponding to received data 215 and may write the data 215 and the ECC bits 220 to the array 235 (e.g., as a codeword). The memory system may also store the ECC bits 220 to an ECC bit register 210 (e.g., a check bit register) of the memory system. The memory system may subsequently receive and write an error vector to the memory array. For example, during the second portion of the test, a host system may modify (e.g., flip) one or more bits of the data 215 and transmit modified data 217 to the memory system. Rather than use new ECC bits 220 corresponding to the modified data 217 (e.g., error vector) for storage to the array 235, the memory system may output the ECC bits 220 from the ECC bit register 210 to the array 235 for storage with the modified data 217 (e.g., as a codeword). In some examples, upon receiving the error vector (e.g., the modified data 217), the system 100 may refrain from generating new ECC bits, may retrieve the old ECC bits from the ECC bit register 210, and may then store the old ECC bits in a location of the array 235 that corresponds to the error vector (e.g., the modified data 217). In some examples, upon receiving the error vector (e.g., the modified data 217), the system 100 may generate the new ECC bits, but may discard the newly generated ECC bits. Instead, the system 100 may retrieve the old ECC bits from the ECC bit register 210 and may then store the old ECC bits in a location of the array 235 that corresponds to the error vector (e.g., the modified data 217).

The memory system may subsequently access the modified data 217 and the ECC bits 220 from the array 235. Using the ECC bits 220, the memory system may detect one or more errors in the modified data 217 and transmit the modified data 217 and an indication that the modified data 217 includes the one or more errors (e.g., a severity indication) to the host system. The modified data 217 and the indication may enable the host system to verify whether the error detection and correction performance of the memory system along the entire data path, for example, by determining whether the quantity and location of the errors corresponds to those bits that were flipped by the host system. Verifying the error detection and correction performance of the memory system along the entire data path supports adjustments and corrections to the ECC circuitry of the memory system, which may increase reliability of the memory system, decrease access latency, and improve efficiency of the memory system

In an example, the host system may transmit data 215 to the memory system to write the data 215 to the array 235 in accordance with a first portion of a test. As part of a first write operation to write the data 215, the memory system may use the ECC bit generator 205 to generate ECC bits 220 from data 215 for storage to the array 235. The ECC bit generator 205 may output the ECC bits 220 to a multiplexer 230 of the memory system.

The multiplexer may output the ECC bits 220 received from the ECC bit generator 205 in accordance with the first portion of the test based on an input 265. For example, the memory system may include a mode register 270 and a mode register 275 that indicate where test modes of the memory system associated with the mode registers are enabled. For instance, a setting of the mode register 270 may enable or disable a first test mode that indicates for the memory system to perform the first portion of the test, and a setting of the mode register 275 may enable or disable a second test mode that indicates for the memory system to perform a second portion of the test. During the first portion of the test, the memory system may set the mode register 270 to enable the first test mode and set the mode register 275 to disable the second test mode. Accordingly, during the first portion of the test, the input 265 to the multiplexer 230 may indicate that the second test mode is disabled and that the multiplexer is to select the ECC bits 220 from the ECC bit generator 205 for output to the array 235. Thus, as part of the first write operation, the memory system may store the data 215 and the ECC bits 220 to the array 235 (e.g., as a first codeword).

In accordance with the first portion of the test (e.g., the first test mode), the ECC bit generator 205 may also output the ECC bits 220 to the ECC bit register 210 of the memory system (e.g., for storage during the test). For example, the memory system may include a logic gate 255 and a multiplexer 250 with a clock signal 240 and a supply voltage 245 as inputs. The logic gate 255 may receive as inputs an input 260 and the input 265. The input 260 may indicate whether the first test mode is enabled or disabled, and the input 265 may indicate whether the second test mode is enabled or disabled. An output of the logic gate 255 may be input into the multiplexer 250 to select whether the multiplexer is to output the clock signal 240 to the ECC bit register. In accordance with the first test mode being enabled and the second test mode being disabled, the output of the logic gate 255 may indicate for the multiplexer 250 to output the clock signal 240 to the ECC bit register 210 such that the ECC bit register 210 stores the ECC bits 220 received from the ECC bit generator 205.

In the example of FIG. 2, the logic gate 255 is an AND gate with one input corresponding to the input 265 being inverted, however, other types of logic gates or combination of logic gates to support enabling or disabling storage of ECC bits 220 to the ECC bit register 210 are possible.

In some examples, the host system may verify the first write operation. For example, after the first write operation, the host system may transmit a command to the memory system to read the data 215 to determine whether it was successfully written to the array 235 during the first write operation.

After the first write operation is performed and the ECC bits 220 are stored to the ECC bit register 210, a second portion of the test may be performed. For example, in accordance with a second portion of the test, the host system may transmit an error vector to the memory system. For instance, the host system may flip one or more bits of the data 215 and transmit the modified data 217 (e.g., second data, an error vector) to the memory system. The memory system may receive the modified data 217 and may write the modified data 217 to the array 235. In some examples, the ECC bit generator 205 may receive the modified data 217 and generate ECC bits corresponding to the modified data 217, however, in accordance with the second portion of the test, the ECC bits corresponding to the modified data 217 may not be stored to the array 235 with the modified data 217.

For example, after the first write operation is performed and the ECC bits 220 are stored to the ECC bit register, the memory system may set the mode register 270 to disable the first test mode and set the mode register 275 to enable the second test mode to indicate performance of the second portion of the test. While the second test mode is enabled, the ECC bit register 210 to refrain from storing any ECC bits 220 received from the ECC bit generator 205, for example, in accordance with the output of the logic gate 255. For example, during the second portion of the test (e.g., while the second test mode is enabled), the mode registers 270 and 275 may be set such that the logic gate 255 outputs a signal to the multiplexer 250 that causes the ECC bit register 210 to refrain from storing an input from the ECC bit generator 205 (e.g., by causing the multiplexer 250 to output the supply voltage 245 or not to output a signal). Instead, the ECC bit register 210 may output the ECC bits 220 stored to the ECC bit register 210 as part of the first write operation to the multiplexer 230.

Based on enabling the second test mode, the input 265 may indicate for the multiplexer 230 to select the ECC bits 220 received from the ECC bit register 220 to output to the array 235 for storage with the modified data 217 as part of the second write operation. Accordingly, as part of the second write operation, the ECC bits 220 corresponding to the data 215 may be stored with the modified data 217 to the array 235 (e.g., as a second codeword).

In some examples, the memory system may perform one or more other write operations while the second test mode is enabled. In each of these write operations, modified data (e.g., the data 215 modified in a different way than the modified data 217) may be stored to the array 235 with the ECC bits 220 corresponding to the data 215 that were stored to the ECC bit register 210 while the first test mode was enabled. Similarly, newly generated ECC bits from the modified data may be disregarded and the ECC bit register 210 may continue to output the stored ECC bits 220 as part of corresponding write operations (e.g., until second the memory system exits the second test mode).

In some examples, to prevent a host system from having direct access to the array 235, read and write commands performed during the test may limit the operations, such as to one row, one column, or one bank limitation (e.g., one burst), and the memory system may store the data in the intermediate sense amplifiers (e.g., without an active bank mechanism). In some cases, to support such limitations, banks of the memory system may be in a precharge state prior to entering the first test mode (e.g., prior to initiating the first portion of the test). Additionally, or alternatively, row activation during the test (e.g., while the first test mode or the second test mode is enabled) may be ignored.

By utilizing a full data path to write data vectors and associated error vectors (e.g., data vectors with errors injected) to the array 235, the memory system may be able to provide information associated with the performance of the memory system to the host system to support adjustments to error correction and detection circuitry of the memory system. For example, the host system may retrieve the error vector (e.g., the modified data 217) from the array 235 and may compare the modified data 217 to expected data to determine the location and severity of errors within the data (e.g., by utilizing knowledge of the errors injected into the error vector). The host system may use the location of the errors, severity of the errors, and other test information to adjust or correct various operations by the memory system, host system, or both, which may improve error correction and detection reliability and performance, decrease latency, and increase the efficiency of the memory system, among other benefits.

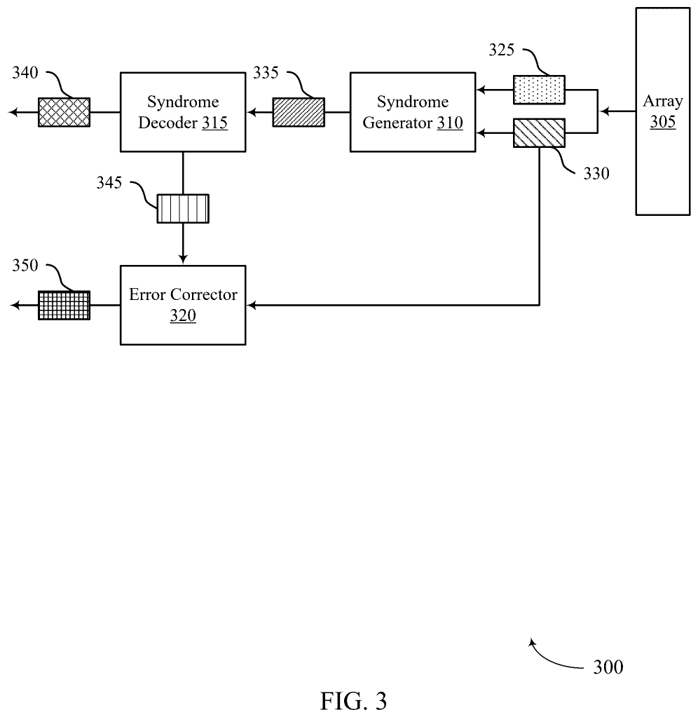

FIG. 3 shows an example of a test diagram 300 that supports systems and techniques for error testing in accordance with examples as disclosed herein. The test diagram 300 may be implemented by aspects of a system 100 or one or more components thereof. For example, the test diagram 300 depicts components of a memory system described herein, including with reference to FIGS. 1 and 2) that support testing error detection and correction performance of the memory system in conjunction with writing data to and reading data from a memory array (e.g., a memory array 155).

The memory system may include ECC circuitry that supports performing error detection and correction operations on data stored to an array 305 (e.g., a memory array 155, an array 235) using ECC bits stored to the array 305 (e.g., ECC bits included in a codeword that includes the data and the ECC bits). For example, the memory system may include a syndrome generator 310. In response to a read command from a host system, the memory system may read ECC bits 325 (e.g., ECC bits 220) and data 330 (e.g., a codeword) from the array 305. The data 330 may be modified data 217 written to the array 305 during a second portion of a test (e.g., while a mode register 275 is set to enable a second test mode), as described with reference to FIG. 2. In some examples, the read command may be received and performed as part of the second portion of the test (e.g., while the second test mode is enabled). The syndrome generator 310 may receive the ECC bits 325 and the data 330 from the array 305. The syndrome generator 310 may use the ECC bits 325 and the data 330 to generate and output a syndrome 335 to a syndrome decoder 315 of the memory system

The syndrome decoder 315 may receive the syndrome 335 from the syndrome generator 310. Using the syndrome 335, the syndrome decoder 315 may determine whether the ECC bits 325 indicate the presence of one or more errors in the data 330. If there are one or more errors present, the syndrome decoder 315 may determine the quantity of errors and the location of the errors in the data 330. The syndrome decoder 315 may output an error location indication 345 that indicates the location of the one or more errors in the data 330. The syndrome decoder 315 may also output an indication of whether the data 330 includes any errors, which may be referred to as a severity indication 340. In some examples, the syndrome decoder 315 may output the error location indication 345 to an error corrector 320 of the memory system and may output the severity indication 340 to the host system (e.g., via processing circuitry of the memory system).

The error corrector 320 may receive the error location indication 345 from the syndrome decoder 315 and the data 330 from the array 305. The error corrector 320 may utilize the error location indication 345 to locate and correct one or more errors in the data 330. In some examples, the error corrector 320 may correct 1-bit errors in the data 330 and may detect bit errors in excess of one bit in the data 330. Based on correcting the one or more errors, the error corrector 320 may output corrected data 350 to the host system (e.g., via processing circuitry of the memory system).

The host system may receive the corrected data 350 and the severity indication 340 and determine various performance characteristics of the memory system. For example, the severity indication 340 may indicate to the host system the presence of one or more errors in the data 330 retrieved from the array 305. Because the data 330 was written as an error vector (e.g., corresponds to modified data 217) and the ECC bits 325 correspond to other data (e.g., data 215), the host system may expect the ECC circuitry of the memory system to detect errors at the locations where the host system modified the data during the second portion of the test. That is, if the ECC circuitry of the memory system operates correctly, the memory system may indicate that the data 330 includes errors at the bits that the host system flipped to generate the modified data 217. Accordingly, the severity indication 340 may indicate to the host system that the data 330 included one or more errors, and the data 350 may indicate to the host system the location of the one or more errors within the data 330. If the location of the one or more errors correspond to the bits modified by the host system in writing the modified data 217, the host system may determine (e.g., verify) that the ECC circuitry of the memory system is operating correctly (e.g., that the ECC bits 325 were generated and written to the array 305 correctly).

Alternatively, if the location of the one or more errors or the quantity of the one or more errors is different than the location or quantity of bits modified by the host system in writing the modified data 217, the host system may determine that an error occurred somewhere along the data path (e.g., while generating the ECC bits 325, storing the data 330 to the array 305, accessing the data 330, performing operations on the data 330).

In some examples, other data vectors may be read from the array 305 such that multiple error vectors may be tested. For example, the memory system may store one or more other error vectors to the array 305 while the second test mode is enabled that have different injected errors than the data 330 (e.g., as described with reference to FIG. 2). The memory system may similarly provide corresponding severity indications 340 and corrected data 350 to the host system such that the host system may test different error conditions and error correction and detection capabilities of the ECC circuitry.

After the second portion of the test, the memory system may disable mode registers that enable the first and second test modes (e.g., mode registers 270 and 275) to exit the test. For example, after performing a read operation to read the data 330 and ECC bits 325, the memory system may set the mode register 275 to disable the second test mode.

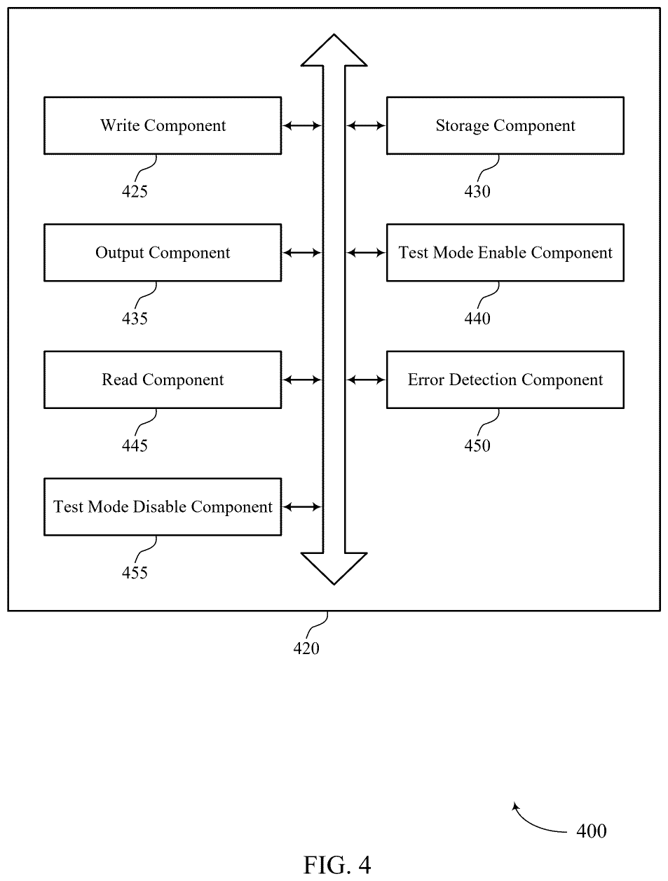

FIG. 4 shows a block diagram 400 of a memory system 420 that supports systems and techniques for error testing in accordance with examples as disclosed herein. The memory system 420 may be an example of aspects of a memory system as described with reference to FIGS. 1 through 3. The memory system 420, or various components thereof, may be an example of means for performing various aspects of systems and techniques for error testing as described herein. For example, the memory system 420 may include a write component 425, a storage component 430, an output component 435, a test mode enable component 440, a read component 445, an error detection component 450, a test mode disable component 455, or any combination thereof. Each of these components, or components of subcomponents thereof (e.g., one or more processors, one or more memories), may communicate, directly or indirectly, with one another (e.g., via one or more buses).

The write component 425 may be configured as or otherwise support a means for writing, as part of a first write operation, first data and ECC bits associated with the first data to one or more memory arrays of the memory system. The storage component 430 may be configured as or otherwise support a means for storing, in accordance with a first portion of a test and based at least in part on the first write operation, the ECC bits to a register of the memory system. In some examples, the write component 425 may be configured as or otherwise support a means for writing, as part of a second write operation and based at least in part on storing the ECC bits to the register, second data to the one or more memory arrays of the memory system. The output component 435 may be configured as or otherwise support a means for outputting, in accordance with a second portion of the test and as part of the second write operation, the ECC bits from the register to the one or more memory arrays of the memory system.

In some examples, to support writing the second data, the write component 425 may be configured as or otherwise support a means for writing modified first data to the one or more memory arrays, the modified first data corresponding to the first data with one or more bits modified.

In some examples, the read component 445 may be configured as or otherwise support a means for reading the second data and the ECC bits from the one or more memory arrays. In some examples, the error detection component 450 may be configured as or otherwise support a means for detecting, using the ECC bits, one or more errors in the second data based at least in part on the one or more bits of the first data being modified. In some examples, the output component 435 may be configured as or otherwise support a means for outputting the second data and an indication that the second data includes the one or more errors based at least in part on detecting the one or more errors.

In some examples, the one or more errors in the second data corresponding to the modified one or more bits indicates that the ECC bits were generated and written correctly.

In some examples, the one or more errors in the second data corresponding to one or more bits that are different than the modified one or more bits indicates an error associated with the ECC bits.

In some examples, the test mode enable component 440 may be configured as or otherwise support a means for setting a first mode register to enable a first test mode indicating performance of the first portion of the test, where performing the first write operation and storing the ECC bits to the register are based at least in part on enabling the first test mode.

In some examples, the test mode enable component 440 may be configured as or otherwise support a means for setting, after storing the ECC bits to the register, a second mode register to enable a second test mode indicating performance of the second portion of the test, where performing the second write operation and outputting the ECC bits from the register are based at least in part on enabling the second test mode.

In some examples, the test mode disable component 455 may be configured as or otherwise support a means for disabling, after outputting the ECC bits from the register, the first mode register and the second mode register to exit the test.

In some examples, the read component 445 may be configured as or otherwise support a means for reading, as part of a first read operation before the second write operation, the first data from the one or more memory arrays to verify the first write operation.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

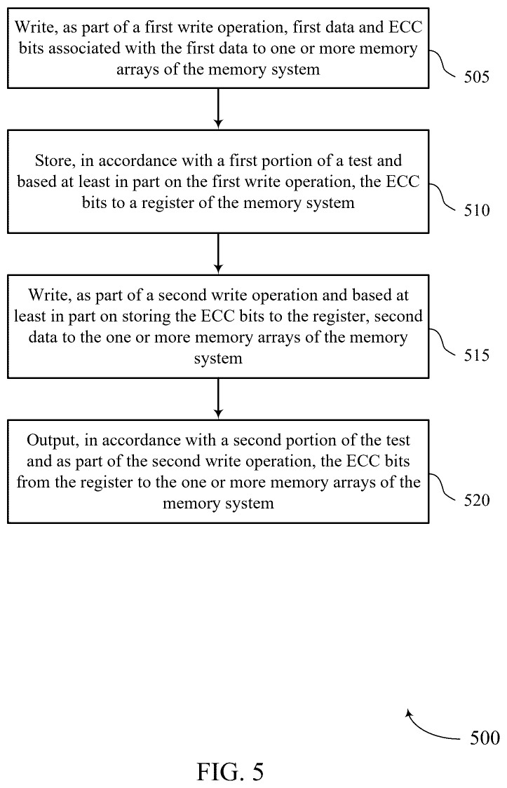

FIG. 5 shows a flowchart illustrating a method 500 that supports systems and techniques for error testing in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include writing, as part of a first write operation, first data and ECC bits associated with the first data to one or more memory arrays of the memory system. In some examples, aspects of the operations of 505 may be performed by a write component 425 as described with reference to FIG. 4.

At 510, the method may include storing, in accordance with a first portion of a test and based at least in part on the first write operation, the ECC bits to a register of the memory system. In some examples, aspects of the operations of 510 may be performed by a storage component 430 as described with reference to FIG. 4.

At 515, the method may include writing, as part of a second write operation and based at least in part on storing the ECC bits to the register, second data to the one or more memory arrays of the memory system. In some examples, aspects of the operations of 515 may be performed by a write component 425 as described with reference to FIG. 4.

At 520, the method may include outputting, in accordance with a second portion of the test and as part of the second write operation, the ECC bits from the register to the one or more memory arrays of the memory system. In some examples, aspects of the operations of 520 may be performed by an output component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for writing, as part of a first write operation, first data and ECC bits associated with the first data to one or more memory arrays of the memory system; storing, in accordance with a first portion of a test and based at least in part on the first write operation, the ECC bits to a register of the memory system; writing, as part of a second write operation and based at least in part on storing the ECC bits to the register, second data to the one or more memory arrays of the memory system; and outputting, in accordance with a second portion of the test and as part of the second write operation, the ECC bits from the register to the one or more memory arrays of the memory system.

Aspect 2: The method, apparatus, or non-transitory computer-readable medium of aspect 1, wherein writing the second data further includes operations, features, circuitry, logic, means, or instructions, or any combination thereof for writing modified first data to the one or more memory arrays, the modified first data corresponding to the first data with one or more bits modified.

Aspect 3: The method, apparatus, or non-transitory computer-readable medium of aspect 2, further including operations, features, circuitry, logic, means, or instructions, or any combination thereof for reading the second data and the ECC bits from the one or more memory arrays; detecting, using the ECC bits, one or more errors in the second data based at least in part on the one or more bits of the first data being modified; and outputting the second data and an indication that the second data includes the one or more errors based at least in part on detecting the one or more errors.

Aspect 4: The method, apparatus, or non-transitory computer-readable medium of aspect 3, where the one or more errors in the second data corresponding to the modified one or more bits indicates that the ECC bits were generated and written correctly.

Aspect 5: The method, apparatus, or non-transitory computer-readable medium of aspect 3, where the one or more errors in the second data corresponding to one or more bits that are different than the modified one or more bits indicates an error associated with the ECC bits.

Aspect 6: The method, apparatus, or non-transitory computer-readable medium of

any of aspects 1 through 5, further including operations, features, circuitry, logic, means, or instructions, or any combination thereof for setting a first mode register to enable a first test mode indicating performance of the first portion of the test, where performing the first write operation and storing the ECC bits to the register are based at least in part on enabling the first test mode.

Aspect 7: The method, apparatus, or non-transitory computer-readable medium of

aspect 6, further including operations, features, circuitry, logic, means, or instructions, or any combination thereof for setting, after storing the ECC bits to the register, a second mode register to enable a second test mode indicating performance of the second portion of the test, where performing the second write operation and outputting the ECC bits from the register are based at least in part on enabling the second test mode.

Aspect 8: The method, apparatus, or non-transitory computer-readable medium of aspect 7, further including operations, features, circuitry, logic, means, or instructions, or any combination thereof for disabling, after outputting the ECC bits from the register, the first mode register and the second mode register to exit the test.

Aspect 9: The method, apparatus, or non-transitory computer-readable medium of any of aspects 1 through 8, further including operations, features, circuitry, logic, means, or instructions, or any combination thereof for reading, as part of a first read operation before the second write operation, the first data from the one or more memory arrays to verify the first write operation.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: A memory system, including: one or more memory arrays; a register coupled with the one or more memory arrays; and an error control information generator coupled with the one or more memory arrays and the register and configured to output, as part of a first write operation and in accordance with a first portion of a test, ECC bits to the one or more memory arrays and to the register, where the register is configured to output, as part of a second write operation and in accordance with a second portion of the test, the ECC bits to the one or more memory arrays.

Aspect 11: The memory system of aspect 10, further including: processing circuitry coupled with the one or more memory arrays and configured to cause the memory system to: write, as part of the first write operation, first data to the one or more memory arrays, where the ECC bits are associated with the first data; and write, as part of the second write operation, second data to the one or more memory arrays, the second data corresponding to the first data with one or more modified bits.

Aspect 12: The memory system of aspect 11, further including: error correction circuitry coupled with the one or more memory arrays and configured to: receive, from the one or more memory arrays as part of a read operation, the ECC bits and the second data; detect, using the ECC bits, one or more errors in the second data based at least in part on the one or more bits of the first data being modified; and output the second data and an indication that the second data includes the one or more errors based at least in part on detecting the one or more errors.

Aspect 13: The memory system of aspect 12, where the one or more errors in the second data corresponding to the modified one or more bits indicates that the ECC bits were generated and written correctly.

Aspect 14: The memory system of aspect 12, where the one or more errors in the second data corresponding to one or more bits that are different than the modified one or more bits indicates an error associated with writing the first data and the ECC bits.

Aspect 15: The memory system of any of aspects 10 through 14, further including: a multiplexer coupled with the error control information generator and the register, the multiplexer configured to receive the ECC bits from the error control information generator and the register and to output the ECC bits to the one or more memory arrays.

Aspect 16: The memory system of any of aspects 10 through 15, further including: a first mode register configured to enable a first test mode indicating performance of the first portion of the test, where the error control information generator is configured to output the ECC bits to the one or more memory arrays and to the register based at least in part on the first mode register enabling the first test mode.

Aspect 17: The memory system of aspect 16, further including: a second mode register configured to enable a second test mode indicating performance of the second portion of the test, where the register is configured to output the ECC bits to the one or more memory arrays based at least in part on the second mode register enabling the second test mode.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method by a memory system, comprising:
writing, as part of a first write operation, first data and error correction code bits associated with the first data to one or more memory arrays of the memory system;
storing, in accordance with a first portion of a test and based at least in part on the first write operation, the error correction code bits to a register of the memory system;
writing, as part of a second write operation and based at least in part on storing the error correction code bits to the register, second data to the one or more memory arrays of the memory system; and
outputting, in accordance with a second portion of the test and as part of the second write operation, the error correction code bits from the register to the one or more memory arrays of the memory system.

2. The method of claim 1, wherein writing the second data comprises:
writing modified first data to the one or more memory arrays, the modified first data corresponding to the first data with one or more bits modified.

3. The method of claim 2, further comprising:
reading the second data and the error correction code bits from the one or more memory arrays;
detecting, using the error correction code bits, one or more errors in the second data based at least in part on the one or more bits of the first data being modified; and
outputting the second data and an indication that the second data includes the one or more errors based at least in part on detecting the one or more errors.

4. The method of claim 3, wherein the one or more errors in the second data corresponding to the modified one or more bits indicates that the error correction code bits were generated and written correctly.

5. The method of claim 3, wherein the one or more errors in the second data corresponding to one or more bits that are different than the modified one or more bits indicates an error associated with the error correction code bits.

6. The method of claim 1, further comprising:
setting a first mode register to enable a first test mode indicating performance of the first portion of the test, wherein performing the first write operation and storing the error correction code bits to the register are based at least in part on enabling the first test mode.

7. The method of claim 6, further comprising:
setting, after storing the error correction code bits to the register, a second mode register to enable a second test mode indicating performance of the second portion of the test, wherein performing the second write operation and outputting the error correction code bits from the register are based at least in part on enabling the second test mode.

8. The method of claim 7, further comprising:
disabling, after outputting the error correction code bits from the register, the first mode register and the second mode register to exit the test.

9. The method of claim 1, further comprising:
reading, as part of a first read operation before the second write operation, the first data from the one or more memory arrays to verify the first write operation.

10. A memory system, comprising:
one or more memory arrays;
a register coupled with the one or more memory arrays; and
an error control information generator coupled with the one or more memory arrays and the register and configured to output, as part of a first write operation and in accordance with a first portion of a test, error correction code bits to the one or more memory arrays and to the register,
wherein the register is configured to output, as part of a second write operation and in accordance with a second portion of the test, the error correction code bits to the one or more memory arrays.

11. The memory system of claim 10, further comprising:
processing circuitry coupled with the one or more memory arrays and configured to cause the memory system to:
write, as part of the first write operation, first data to the one or more memory arrays, wherein the error correction code bits are associated with the first data; and
write, as part of the second write operation, second data to the one or more memory arrays, the second data corresponding to the first data with one or more modified bits.

12. The memory system of claim 11, further comprising:
error correction circuitry coupled with the one or more memory arrays and configured to:
receive, from the one or more memory arrays as part of a read operation, the error correction code bits and the second data;
detect, using the error correction code bits, one or more errors in the second data based at least in part on one or more bits of the first data being modified; and
output the second data and an indication that the second data includes the one or more errors based at least in part on detecting the one or more errors.

13. The memory system of claim 12, wherein the one or more errors in the second data corresponding to the modified one or more bits indicates that the error correction code bits were generated and written correctly.

14. The memory system of claim 12, wherein the one or more errors in the second data corresponding to one or more bits that are different than the modified one or more bits indicates an error associated with writing the first data and the error correction code bits.

15. The memory system of claim 10, further comprising:
a multiplexer coupled with the error control information generator and the register, the multiplexer configured to receive the error correction code bits from the error control information generator and the register and to output the error correction code bits to the one or more memory arrays.

16. The memory system of claim 10, further comprising:
a first mode register configured to enable a first test mode indicating performance of the first portion of the test, wherein the error control information generator is configured to output the error correction code bits to the one or more memory arrays and to the register based at least in part on the first mode register enabling the first test mode.

17. The memory system of claim 16, further comprising:
a second mode register configured to enable a second test mode indicating performance of the second portion of the test, wherein the register is configured to output the error correction code bits to the one or more memory arrays based at least in part on the second mode register enabling the second test mode.

18. A memory system, comprising:
one or more memory devices; and
processing circuitry coupled with the one or more memory devices and configured to cause the memory system to:
write, as part of a first write operation, first data and error correction code bits associated with the first data to one or more memory arrays of the memory system;
store, in accordance with a first portion of a test and based at least in part on the first write operation, the error correction code bits to a register of the memory system;
write, as part of a second write operation and based at least in part on storing the error correction code bits to the register, second data to the one or more memory arrays of the memory system; and
output, in accordance with a second portion of the test and as part of the second write operation, the error correction code bits from the register to the one or more memory arrays of the memory system.

19. The memory system of claim 18, wherein, to write the second data, the processing circuitry is configured to cause the memory system to:
write modified first data to the one or more memory arrays, the modified first data corresponding to the first data with one or more bits modified.

20. The memory system of claim 19, wherein the processing circuitry is further configured to cause the memory system to:
read the second data and the error correction code bits from the one or more memory arrays;
detect, using the error correction code bits, one or more errors in the second data based at least in part on the one or more bits of the first data being modified; and
output the second data and an indication that the second data includes the one or more errors based at least in part on detecting the one or more errors.

21. The memory system of claim 20, wherein the one or more errors in the second data corresponding to the modified one or more bits indicates that the error correction code bits were generated and written correctly.

22. The memory system of claim 20, wherein the one or more errors in the second data corresponding to one or more bits that are different than the modified one or more bits indicates an error associated with the error correction code bits.

23. The memory system of claim 18, wherein the processing circuitry is further configured to cause the memory system to:
set a first mode register to enable a first test mode indicating performance of the first portion of the test, wherein performing the first write operation and storing the error correction code bits to the register are based at least in part on enabling the first test mode.

24. The memory system of claim 23, wherein the processing circuitry is further configured to cause the memory system to:
set, after storing the error correction code bits to the register, a second mode register to enable a second test mode indicating performance of the second portion of the test, wherein performing the second write operation and outputting the error correction code bits from the register are based at least in part on enabling the second test mode.

25. The memory system of claim 24, wherein the processing circuitry is further configured to cause the memory system to:
disable, after outputting the error correction code bits from the register, the first mode register and the second mode register to exit the test.
